(19) United States
(12) Patent Application Publication
(10) Pub. No.: US 2023/0180438 A1
(43) Pub. Date: Jun. 8, 2023

(54) SERVER AND HEAT EXCHANGER

(71) Applicants: Inventec(Pudong)Technology Corporation, Shanghai (CN); INVENTEC CORPORATION, tAIPEI (TW)

(72) Inventors: Minqian Xie, Shanghai (CN); Shukang Han, Shanghai (CN); Lian-Fei Zhang, Shanghai (CN); Ke Sun, Shanghai (CN); Pin-Yi Xiang, Shanghai (CN)

(21) Appl. No.: 17/693,548

(22) Filed: Mar. 14, 2022

(30) Foreign Application Priority Data
Dec. 7, 2021 (CN) 202111485450.0

(51) Int. Cl. H05K 7/20; F28F 3/02; F28D 15/02; F28D 21/00

(52) U.S. Cl. CPC H05K 7/20381; F28D 15/0275; F28D 21/00; F28F 3/02; F28D 2021/0028

(57) ABSTRACT

A server including a chassis, a motherboard, a heat source and a heat exchanger. The motherboard is disposed in the chassis. The heat source is disposed on and electrically connected to the motherboard. The heat exchanger includes a first chamber body, a plurality of heat dissipation plates and a plurality of heat dissipation fins. The first chamber body is in thermal contact with the heat source and has a first channel. The plurality of heat dissipation plates are in thermal contact with and inserted into the first chamber body. The plurality of heat dissipation plates each have a second channel. The first channel of the first chamber body is in fluid communication with the second channels of the plurality of heat dissipation plates. The plurality of heat dissipation fins are in thermal contact with the plurality of heat dissipation plates.

### CROSS-REFERENCE TO RELATED APPLICATIONS

This non-provisional application claims priority under 35 U.S.C. § 119(a) on Patent Application No(s). 202111485450.0 filed in China, on Dec. 7, 2021, the entire contents of which are hereby incorporated by reference.

### BACKGROUND OF THE INVENTION

### Technical Field of the Invention

The invention relates to a sever and a heat exchanger, more particularly to a server and a heat exchanger including a heat dissipation pate having a channel formed therein.

### Description of the Related Art

In order to dissipate the heat generated by a heat source, a heat exchanger in thermal contact with the heat source is usually disposed in an electronic device. A typical heat exchanger includes a thermally conductive piece, at least one heat pipe and a fin assembly. The thermally conductive piece is in thermal contact with the heat source. Two opposite ends of the heat pipe are in thermal contact with the thermally conductive piece and the fin assembly, respectively.

However, since the heat pipe has high thermal resistance, large volume and heavy weight, the structure of the heat exchanger including heat pipe is complex, and the heat generated by the heat source is inefficiently dissipated via such heat exchanger including heat pipe in a limited space.

### SUMMARY OF THE INVENTION

The invention is to provide a server and a heat exchanger to efficiently dissipate the heat generated by the heat source in a limited space.

One embodiment of this invention provides a server including a chassis, a motherboard, a heat source and a heat exchanger. The motherboard is disposed in the chassis. The heat source is disposed on and electrically connected to the motherboard. The heat exchanger includes a first chamber body, a plurality of heat dissipation plates and a plurality of heat dissipation fins. The first chamber body is in thermal contact with the heat source and has a first channel. The plurality of heat dissipation plates are in thermal contact with and inserted into the first chamber body. The plurality of heat dissipation plates each have a second channel. The first channel of the first chamber body is in fluid communication with the second channels of the plurality of heat dissipation plates. The plurality of heat dissipation fins are in thermal contact with the plurality of heat dissipation plates.

Another embodiment of this invention provides a heat exchanger configured to be in thermal contact with a heat source and accommodate a working fluid. The heat exchanger includes a first chamber body, a plurality of heat dissipation plates and a plurality of heat dissipation fins. The first chamber body is configured to be in thermal contact with the heat source and has a first channel. The plurality of heat dissipation plates are in thermal contact with and inserted into the first chamber body. The plurality of heat dissipation plates each have a second channel. The first channel of the first chamber body is in fluid communication with the second channels of the plurality of heat dissipation plates. The first channel and the second channels are configured to accommodate the working fluid. The plurality of heat dissipation fins are in thermal contact with the plurality of heat dissipation plate.

According to the server and the heat exchanger discussed above, the first channel of the first chamber body is in fluid communication with the second channels of the heat dissipation plates, and the heat dissipation fins are in thermal contact with the heat dissipation plates. Thus, after the working fluid in the first channel of the first chamber body absorbs the heat generated by the heat source, it can be efficiently cooled in the second channels of the heat dissipation plates with the help of the heat dissipation fins. Accordingly, the heat exchanger can efficiently dissipate the heat generated by the heat source in a limited space.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a partially side cross-sectional view of a server according to an embodiment of the invention;

FIG. 2 is a perspective view of a heat exchanger of the server in FIG. 1;

FIG. 3 is a partially enlarged side cross-sectional view of the heat exchanger in FIG. 2;

FIG. 4 is a partially side cross-sectional view of a first chamber body of the heat exchanger in FIG. 2;

FIG. 5 is a photo of a capillary structure of the heat exchanger in FIG. 2;

FIG. 6 is a partially enlarged side view of the heat exchanger in FIG. 2; and

FIG. 7 is a partially enlarged side cross-sectional view of the heat exchanger in FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

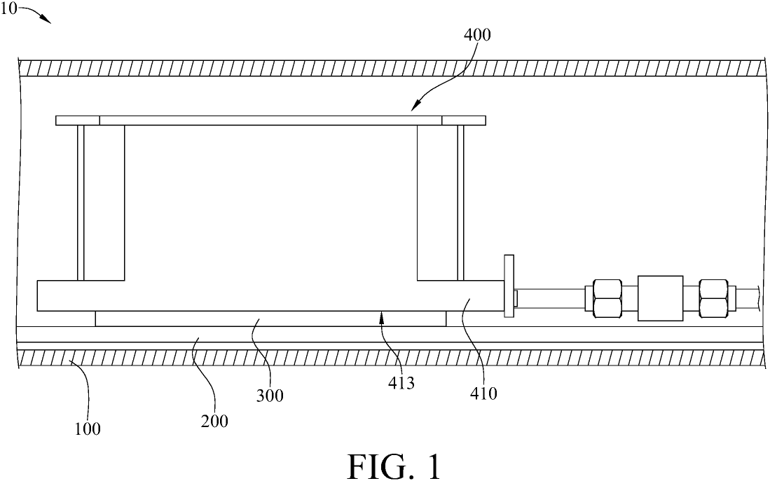

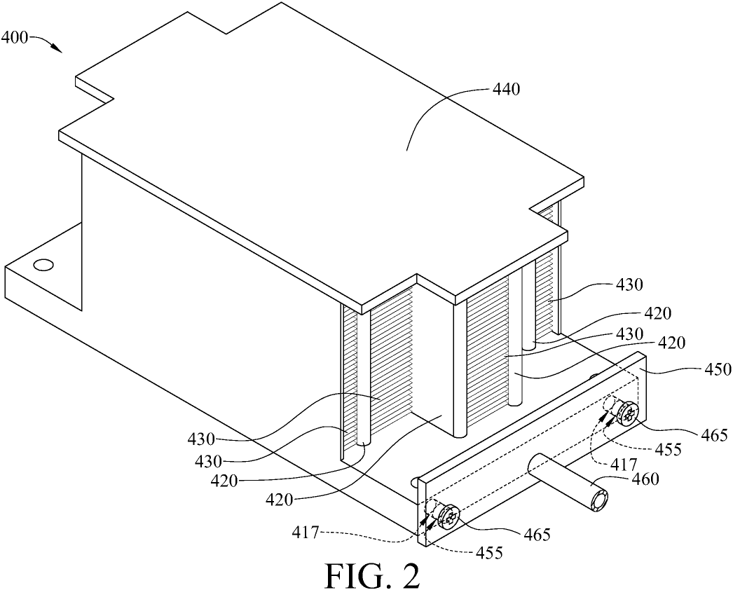

Please refer to FIGS. 1 and 2, where FIG. 1 is a partially side cross-sectional view of a server 10 according to an embodiment of the invention, and FIG. 2 is a perspective view of a heat exchanger 400 of the server in FIG. 1. In this embodiment, the server 10 includes a chassis 100, a motherboard 200, a heat source 300 and the heat exchanger 400. The motherboard 200 is disposed in the chassis 100. The heat source 300 is disposed on and electrically connected to the motherboard 200. The heat source 300 is, for example, a central processing unit (CPU) or a graphic processing unit (GPU).

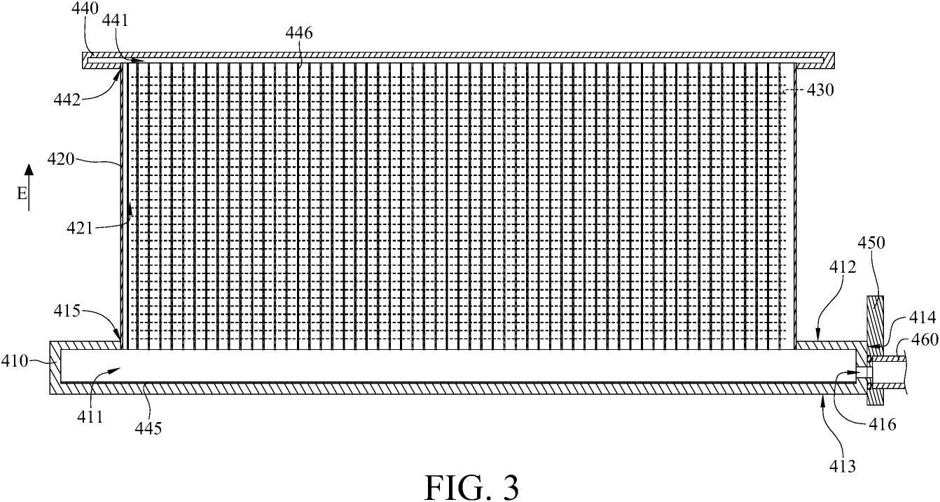

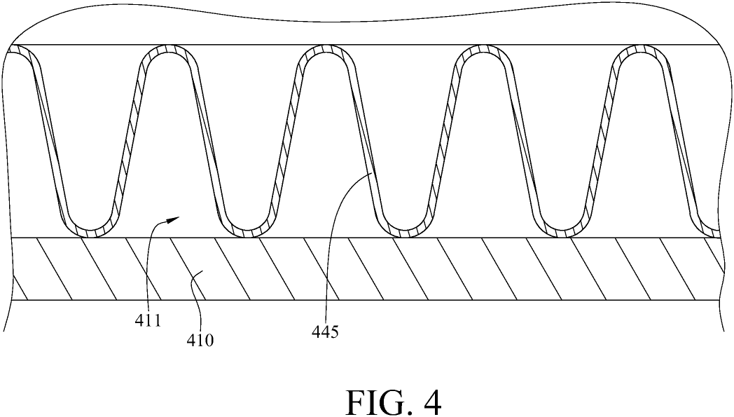

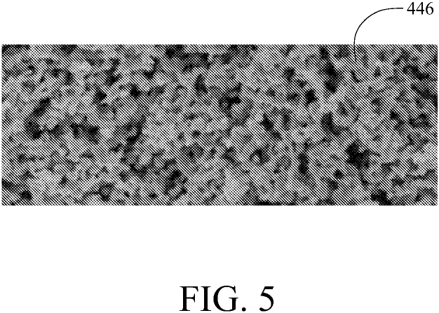

Please refer to FIGS. 1 to 5, where FIG. 3 is a partially enlarged side cross-sectional view of the heat exchanger 400 in FIG. 2, FIG. 4 is a partially side cross-sectional view of a first chamber body 410 of the heat exchanger 400 in FIG. 2, and FIG. 5 is a photo of a capillary structure 445 of the heat exchanger in FIG. 2.

The heat exchanger 400 includes a first chamber body 410, a plurality of heat dissipation plates 420 and a plurality of heat dissipation fins 430. The first chamber body 410 is in thermal contact with the heat source 300 and has a first channel 411 formed therein. In this embodiment, the first chamber body 410 further has a cold surface 412, a hot surface 413 and a side peripheral surface 414 facing away from the first channel 411. The cold surface 412 faces away from the hot surface 413. The side peripheral surface 414 connects the cold surface 412 and the hot surface 413. The hot surface 413 is in thermal contact with the heat source 300. The heat dissipation plates 420 are in thermal contact with the cold surface 412 of the first chamber body 410 and are inserted into the first chamber body 410. Each heat dissipation plate 420 has a second channel 421. The first channel 411 of the first chamber body 410 are in fluid communication with the second channels 421 of the heat dissipation plates 420. The heat dissipation fins 430 are in thermal contact with the heat dissipation plates 420. In addition, in this embodiment, the heat dissipation plates 420 are in, for example, a plate shape.

In this embodiment, the first chamber body 410 further has a plurality of first insertion recesses 415. The first insertion recesses 415 are located at the cold surface 412 and are in fluid communication with the first channel 411. The heat dissipation plates 420 are inserted in the first insertion recesses 415, respectively. In other embodiments, the first insertion recesses may be located at the side peripheral surface and extend from the side peripheral surface to a side of the cold surface located farthest from the hot surface. Alternatively, in still other embodiments, the heat dissipation plates may be inserted into the first insertion recesses and the first channel, and may be in contact with an inner bottom surface of the first chamber body forming the first channel. In such embodiments, each heat dissipation plate may have an opening in fluid communication with the first channel and located at a side of each heat dissipation plate in contact with the inner bottom surface.

In this embodiment, the heat dissipation plates 420 extend along an extension direction E away from the cold surface 412 of the first chamber body 410. The heat dissipation fins 430 are located between the heat dissipation plates 420, and are arranged along the extension direction E. In other embodiments, the heat dissipation fins may be arranged along another direction that is non-parallel to the extension direction of the heat dissipation plates.

In this embodiment, the heat exchanger 400 further includes a second chamber body 440. The second chamber body 440 has a third channel 441 and a plurality of second insertion recesses 442 that are in fluid communication with the third channel 441. Sides of the heat dissipation plates 420 located farthest away from the first chamber body 410 are in thermal contact with the second chamber body 440, and are respectively inserted into the second insertion recesses 442 of the second chamber body 440. The third channel 441 is in fluid communication with the first channel 411 of the first chamber body 410 via the second channels 421 of the heat dissipation plates 420. In other embodiments, the heat exchanger may not include the second chamber body 440, and in such embodiments, sides of the heat dissipation plates located farthest from the first chamber body may be closed ends. In other embodiments, the heat dissipation plates may be inserted into the second insertion recesses and the third channel, and may be in contact with an inner top surface of the second chamber body forming the third channel. In such embodiments, each heat dissipation plate may have an opening in fluid communication with the third channel and located at a side of each heat dissipation plate in contact with the inner top surface.

Note that FIGS. 3 and 4 are cross-sectional views taking along different cross sections. As shown in FIGS. 3 and 4, in this embodiment, the heat exchanger 400 further includes a fin assembly 445. The fin assembly 445 is located in the first channel 411 of the first chamber body 410. The fin assembly 445 is in, for example, a wave shape. In other embodiments, the heat exchanger may not include the fin assembly 445.

Also, as shown in FIGS. 3 to 5, in this embodiment, the heat exchanger 400 further includes a plurality of capillary structures 446 respectively located in the second channels 421 of the heat dissipation plates 420. As shown in FIG. 5, the capillary structures 446 are in, for example, a porous shape, and is, for example, a sintering structure made by sintering copper powder. In other embodiments, the heat exchanger may not include the capillary structure 446.

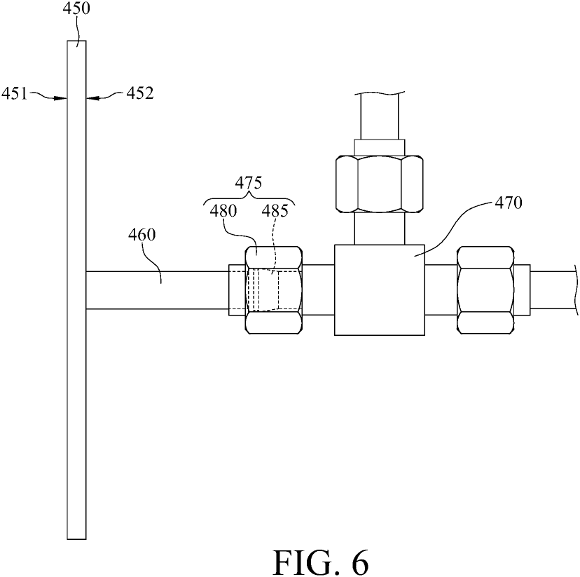

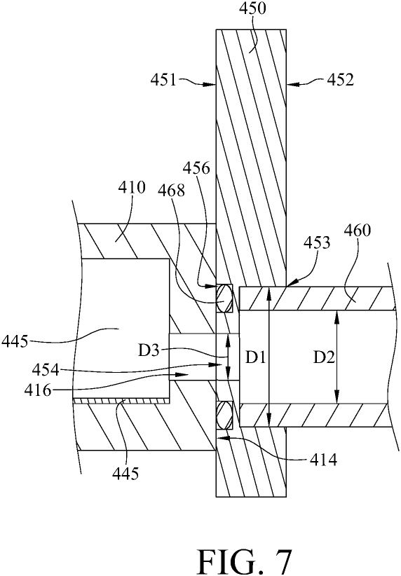

Please refer to FIGS. 6 and 7, where FIG. 6 is a partially enlarged side view of the heat exchanger 400 in FIG. 2, and FIG. 7 is a partially enlarged side cross-sectional view of the heat exchanger 400 in FIG. 2.

In this embodiment, the first chamber body 410 further has an opening 416, and the heat exchanger 400 further includes a mounting plate 450, a tube 460 and a valve 470. In this embodiment, the opening 416 of the first chamber body 410 is in fluid communication with the first channel 411, and is located at the side peripheral surface 414. In this embodiment, the mounting plate 450 is fixed to the side peripheral surface 414 of the first chamber body 410. The mounting plate 450 has a first surface 451, a second surface 452, a mounting hole 453 and a connection hole 454. The first surface 451 and the second surface 452 face away from each other. The first surface 451 is located closer to the first chamber body 410 than the second surface 452. The connection hole 454 is located at the first surface 451. The mounting hole 453 is located at the second surface 452 and is in fluid communication with the connection hole 454. An end of the tube 460 is accommodated in the mounting hole 453 and is in fluid communication with the connection hole 454. The valve 470 is installed on the other end of the tube 460 and is in fluid communication with the tube 460. That is, in this embodiment, the valve 470 is installed on the first chamber body 410 via the mounting plate 450 and the tube 460, and is in fluid communication with the opening 416 of the first chamber body 410. In this embodiment, the valve 470 is, for example, a three-way valve.

In this embodiment, please refer to FIG. 2 again, the heat exchanger 400 further includes two screws 465, the first chamber body 410 further has two first screw holes 417 that are spaced apart from each other, and the mounting plate 450 further has two second screw holes 455 that are spaced apart from each other. The two first screw holes 417 are located at the side peripheral surface 414. The two second screw holes 455 are disposed through the first surface 451 and the second surface 452, and are spaced apart from the connection hole 454. The two screws 465 are respectively screwed into the two first screw holes 417 and the two second screw holes 455 to fix the mounting plate 450 to the first chamber body 410. In other embodiments, the heat exchanger may merely include one screw, and in such embodiments, the first chamber body merely has one first screw hole and the mounting plate merely has one second screw hole. Alternatively, in still other embodiments, the heat exchanger may not include the screw 465, and in such embodiments, the first chamber body may not have the first screw hole 417, the mounting plate may not have the second screw hole 455, and the mounting plate may be adhered to the side peripheral surface of the first chamber body.

Please refer to FIGS. 6 and 7 again, in this embodiment, an end of the tube 460 is fixed to the mounting plate 450 via, for example, welding or soldering, but the invention is not limited thereto. In other embodiment, an end of the tube may be adhered to the mounting plate.

In this embodiment, as shown in FIG. 7, the heat exchanger 400 further includes a sealing ring 468, and the mounting plate 450 further has an annular recess 456. The annular recess 456 recesses from the first surface 451. The annular recess 456 surrounds the connection hole 454 and is not in fluid communication with the connection hole 454. The sealing ring 468 is accommodated in the annular recess 456 to achieve the seal between the connection hole 454 of the mounting plate 450 and the opening 416 of the first chamber body 410; that is, the sealing ring 468 prevents the connection hole 454 of the mounting plate 450 and the opening 416 of the first chamber body 410 from being in fluid communication with outside environment. In other embodiments, the heat exchanger may not include the sealing ring 468 and the mounting plate may not have the annular recess 456.

In this embodiment, as shown in FIG. 7, a diameter D1 of the mounting hole 453 is greater than a diameter D2 of the tube 460, and the diameter D2 of the tube 460 is greater than a diameter D3 of the connection hole 454. With such configuration, the seal between the mounting plate 450 and the tube 460 is improved. Note that in this embodiment, the diameter D2 of the tube 460 refers to the inner diameter of the tube 460. In other embodiments, the diameter of the mounting hole of the mounting plate, the diameter of the tube and the diameter of the connection hole of the mounting plate may be the same as one another.

In this embodiment, as shown in FIG. 6, the heat exchanger 400 further includes a joint 475 including a nut 480 and a sleeve 485. The other end of the tube 460 is installed on the valve 470 via the nut 480 and the sleeve 485 to improve the seal between the tube 460 and the valve 470. In other embodiments, the heat exchanger may not include the joint 475.

Note that in other embodiments, as long as the tube does not interfere with other components, the mounting plate may be fixed to the cold surface or the hot surface of the first chamber body. In other embodiments, the heat exchanger may not include the mounting plate 450 and the tube 460, and the valve may be directly installed on the first chamber body. In still other embodiments, the heat exchanger may not include the mounting plate 450, the tube 460 and the valve 470.

In this embodiment, the heat exchanger 400 is configured to accommodate a working fluid (not shown) that is, for example, water or refrigerant. Please refer to FIGS. 2, 3 and 6 again, the first channel 411 of the first chamber body 410, the second channels 421 of the heat dissipation plates 420 and the third channel 441 of the second chamber body 440 are configured to accommodate the working fluid. The working fluid in the first channel 411 of the first chamber body 410 absorbs the heat generated by the heat source 300 and thus is vaporized. The gaseous working fluid flows from the first channel 411 to the second channels 421 of the heat dissipation plates 420 via pressure difference therebetween and the help of the capillary structures 446 so as to be condensed with the help of the heat dissipation fins 430. The liquid working fluid in second channel 421 flows to the third channel 441 and then flows back to the first channel 411 of the first chamber body 410 via the second channels 421 of the heat dissipation plates 420. When the valve 470 is closed, the first channel 411, the second channel 421 and the third channel 441 together form an independent close loop allowing the working fluid to circulate and undergo phase transitions therein. That is, the heat exchanger 400 according to the invention do not have any outlet and inlet in fluid communication with external device or component. The opening 416 of the first chamber body 410 is merely to change the working fluid or adjust the amount of the working fluid in the heat exchanger 400 when the valve 470 is opened.

Since the valve 470 is in fluid communication with the first channel 411 of the first chamber body 410 via the opening 416 of the first chamber body 410, the working fluid can be changed or the amount of the working fluid in the heat exchanger 400 can be adjusted merely by opening the valve 470. Accordingly, it is not required to remove the screw 465 from the mounting plate 450 for changing the working fluid or adjusting the amount of the working fluid in the heat exchanger 400, thereby preventing the heat exchanger 400 from leaking the working fluid.

According to the server and the heat exchanger discussed above, the first channel of the first chamber body is in fluid communication with the second channels of the heat dissipation plates, and the heat dissipation fins are in thermal contact with the heat dissipation plates. Thus, after the working fluid in the first channel of the first chamber body absorbs the heat generated by the heat source, it can be efficiently cooled in the second channels of the heat dissipation plates with the help of the heat dissipation fins. Accordingly, the heat exchanger can efficiently dissipate the heat generated by the heat source in a limited space.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A server, comprising:
a chassis;
a motherboard, disposed in the chassis;
a heat source, disposed on and electrically connected to the motherboard; and
a heat exchanger, wherein the heat exchanger comprises a first chamber body, a plurality of heat dissipation plates and a plurality of heat dissipation fins, the first chamber body is in thermal contact with the heat source and has a first channel, the plurality of heat dissipation plates are in thermal contact with and inserted into the first chamber body, the plurality of heat dissipation plates each have a second channel, the first channel of the first chamber body is in fluid communication with the second channels of the plurality of heat dissipation plates, and the plurality of heat dissipation fins are in thermal contact with the plurality of heat dissipation plates.

2. The server according to claim 1, wherein the heat exchanger further comprises a valve, the first chamber body further has an opening in fluid communication with the first channel, and the valve is installed on the first chamber body and in fluid communication with the opening.

3. The server according to claim 2, wherein the heat exchanger further comprises a mounting plate and a tube, the mounting plate is fixed to the first chamber body, the mounting plate has a first surface, a second surface, a mounting hole and a connection hole, the first surface and the second surface face away from each other, the first surface is located closer to the first chamber body than the second surface, the connection hole is located at the first surface, the mounting hole is located at the second surface and is in fluid communication with the connection hole, an end of the tube is accommodated in the mounting hole and is in fluid communication with the connection hole, and the valve is installed on another end of the tube and is in fluid communication with the tube.

4. The server according to claim 3, wherein the end of the tube is fixed to the mounting plate via welding or soldering.

5. The server according to claim 4, wherein a diameter of the mounting hole is greater than a diameter of the tube, and the diameter of the tube is greater than a diameter of the connection hole.

6. The server according to claim 3, wherein the heat exchanger further comprises a joint, and the another end of the tube is installed on the valve via the joint.

7. The server according to claim 3, wherein the heat exchanger further comprises a sealing ring, the mounting plate further has an annular recess, the annular recess recesses from the first surface, the annular recess surrounds the connection hole and is not in fluid communication with the connection hole, and the sealing ring is accommodated in the annular recess.

8. The server according to claim 3, wherein the first chamber body of the heat exchanger further has a cold surface, a hot surface and a side peripheral surface, the cold surface and the hot surface face away from each other, the side peripheral surface connects the cold surface and the hot surface, the hot surface is in thermal contact with the heat source, the plurality of heat dissipation plates are in thermal contact with the cold surface, and the mounting plate is fixed to the side peripheral surface.

9. The server according to claim 3, wherein the heat exchanger further comprises a screw, the first chamber body further has a first screw hole, the mounting plate further has a second screw hole, the second screw hole is located at the first surface and is spaced apart from the connection hole, the screw is screwed into the first screw hole and the second screw hole to fix the mounting plate to the first chamber body.

10. The server according to claim 1, wherein the first chamber body of the heat exchanger has a cold surface, a hot surface and a plurality of insertion recesses, the cold surface and the hot surface face away from each other, the hot surface is in thermal contact with the heat source, the plurality of insertion recesses are located at the cold surface and are in fluid communication with the first channel, the plurality of heat dissipation plates are respectively inserted into the plurality of insertion recesses.

11. The server according to claim 10, wherein the plurality of heat dissipation plates each extend along an extension direction away from the cold surface of the first chamber body, the plurality of heat dissipation fins are located between the plurality of heat dissipation plates and are arranged along the extension direction.

12. The server according to claim 1, wherein the heat exchanger further comprises a second chamber body, sides of the plurality of heat dissipation plates located farthest from the first chamber body are in thermal contact with and inserted into the second chamber body, the second chamber body has a third channel, the third channel is in fluid communication with the first channel of the first chamber body via the second channels of the plurality of heat dissipation plates.

13. A heat exchanger, configured to be in thermal contact with a heat source and accommodate a working fluid, the heat exchanger comprising:
a first chamber body, configured to be in thermal contact with the heat source and having a first channel;
a plurality of heat dissipation plates, wherein the plurality of heat dissipation plates are in thermal contact with and inserted into the first chamber body, the plurality of heat dissipation plates each have a second channel, the first channel of the first chamber body is in fluid communication with the second channels of the plurality of heat dissipation plates, and the first channel and the second channels are configured to accommodate the working fluid; and
a plurality of heat dissipation fins, in thermal contact with the plurality of heat dissipation plate.

14. The heat exchanger according to claim 13, further comprising a valve, wherein the first chamber body further has an opening in fluid communication with the first channel, and the valve is installed on the first chamber body and in fluid communication with the opening.

15. The heat exchanger according to claim 14, further comprising a mounting plate and a tube, wherein the mounting plate is fixed to the first chamber body, the mounting plate has a first surface, a second surface, a mounting hole and a connection hole, the first surface and the second surface face away from each other, the first surface is located closer to the first chamber body than the second surface, the connection hole is located at the first surface, the mounting hole is located at the second surface and is in fluid communication with the connection hole, an end of the tube is accommodated in the mounting hole and is in fluid communication with the connection hole, and the valve is installed on another end of the tube and is in fluid communication with the tube.

16. The heat exchanger according to claim 15, wherein the end of the tube is fixed to the mounting plate via welding or soldering.

17. The heat exchanger according to claim 16, wherein a diameter of the mounting hole is greater than a diameter of the tube, and the diameter of the tube is greater than a diameter of the connection hole.

18. The heat exchanger according to claim 15, further comprising a joint, wherein the another end of the tube is installed on the valve via the joint.

19. The heat exchanger according to claim 15, further comprising a sealing ring, wherein the mounting plate further has an annular recess, the annular recess recesses from the first surface, the annular recess surrounds the connection hole and is not in fluid communication with the connection hole, and the sealing ring is accommodated in the annular recess.

20. The heat exchanger according to claim 13, wherein the working fluid in the first channel of the first chamber body absorbs the heat generated by the heat source and thus is vaporized, the working fluid that is gaseous flows from the first channel to the second channels of the plurality of heat dissipation plates via pressure difference therebetween so as to be condensed with the help of the plurality of heat dissipation fins, the working fluid that is liquid in second channel flows to the third channel and then flows back to the first channel of the first chamber body.
